(19) United States
(12) Patent Application Publication
(10) Pub. No.: US 2024/0071710 A1
(43) Pub. Date: Feb. 29, 2024

(54) METHOD AND APPARATUS FOR NON-INVASIVE SEMICONDUCTOR TECHNIQUE FOR MEASURING DIELECTRIC/SEMICONDUCTOR INTERFACE TRAP DENSITY USING SCANNING ELECTRON MICROSCOPE CHARGING

(71) Applicant: FemtoMetrix, Inc., Los Angeles, CA (US)

(72) Inventor: Timothy M. Wong, Los Angeles, CA (US)

(21) Appl. No.: 18/350,643

(22) Filed: Jul. 11, 2023

Related U.S. Application Data
(60) Provisional application No. 63/400,323, filed on Aug. 23, 2022.
(60) Provisional application No. 63/400,330, filed on Aug. 23, 2022.
(60) Provisional application No. 63/388,398, filed on Jul. 12, 2022.

(51) Int. Cl. H01J 37/02; H01J 37/22; H01J 37/244; H01J 37/28

(52) U.S. Cl. CPC H01J 37/026; H01J 37/226; H01J 37/244; H01J 37/28; H01J 2237/0048

(57) ABSTRACT

A non-invasive semiconductor technique for measuring dielectric/semiconductor interface trap density can be performed by charging the dielectric by creating charges on the top surface of the dielectric layer over the wafer using Scanning Electron Microscope (SEM) charging. This charging can induce an accumulated, a depleted and/or an inverted semiconductor surface. The states of the semiconductor surface can subsequently be measured, identified, and/or quantified using Electric Field Induced Second Harmonic generation (EFISH). From the measured/acquired EFISH versus SEM charge curve, the interface state density (Dᵢₜ) can be extracted. A large working distance provides the ability to create charge and measure the Second Harmonic Generation (SHG) at the same semiconductor surface spot without the needing to move the wafer.

### PRIORITY CLAIM

This application claims the priority benefit of U.S. Patent Prov. App. 63/388,398 entitled METHOD AND APPARATUS FOR NON-INVASIVE, NON-INTRUSIVE, AND UN-GROUNDED, SIMULTANEOUS CORONA DEPOSITION AND SHG MEASUREMENTS, filed Jul. 12, 2022; U.S. Patent Prov. App. 63/400,323, entitled METHOD AND APPARATUS FOR NON-INVASIVE, NON-INTRUSIVE, AND UN-GROUNDED, SIMULTANEOUS CORONA DEPOSITION AND SHG MEASUREMENTS, filed Aug. 23, 2022; and U.S. Patent Prov. App. 63/400,330, entitled METHOD AND APPARATUS FOR NON-INVASIVE SEMICONDUCTOR TECHNIQUE FOR MEASURING DIELECTRIC/SEMICONDUCTOR INTERFACE TRAP DENSITY USING SCANNING ELECTRON MICROSCOPE CHARGING, filed Aug. 23, 2022. Each of the above-noted applications is incorporated herein by reference in its entirety.

### BACKGROUND

### Technical Field

The present invention is in the technical field of semiconductor wafer testing, and more particularly, in the technical field of a non-contact, non-invasive methods for testing such wafers.

### Description of the Related Art

The determination of electrical properties of a dielectric on a semiconductor wafer, an interface between a dielectric and semiconductor, and/or a charge carrier lifetime within the semiconductor wafer can be quite useful in the production of these wafers. Accordingly, systems and methods for determining such electrical properties are disclosed herein.

### SUMMARY

Disclosed herein are systems and methods for measuring at least one electrical property of a semiconductor wafer. Various system and methods comprise using a scanning electron microscope (SEM) or components typically used in an SEM (e.g., electron gun, anode, electron lenses, electron beam deflector) to deposit charge on a top surface of an insulator layer to create a resultant semiconductor surface with an accumulated region, a depletion region, or a depletion region plus an inverted region.

The systems can include an optical system comprising a light source such as a pulsed laser and an optical detector such as a photovoltaic or photomultiplier tube for measuring an optical response of the semiconductor wafer. This optical response may comprise, for example, second harmonic generation (SHG) light having a frequency that is the second harmonic of the frequency of incident pulsed laser light. Accordingly, in various implementations the Electric Field Induced Second Harmonic generation (EFISH) is measured in response to SHG laser stimulus with the addition of surface charge provided by an SEM or SEM components. Various implementations additionally include electronics for determining a characteristic of the sample from the SHG or EFISH signal.

Accordingly, various implementations of the method include, from the response of the second harmonic generation (SHG), determining at least one electrical property of the object area of the semiconductor wafer. Similarly, the system may include electronics configured to determine at least one electrical property of the target area of the sample.

Various implementations of the systems and methods disclosed herein include a technology to measure the density of trapped interface state charge using the change in SHG signal as a function of electron beam charge deposited on the wafer surface, e.g., in scribe lines or any test structures by the SEM or SEM components. This technique can be contactless and can be used in-line, for example, for front-end-of-line (FEOL) wafer processing. The SHG interrogating laser spot size can be on the order of 100 μm (microns or micrometers) or 80 μm or 50 μm or 30 μm or 20 μm or 10 μm or any range formed by any of these values or possibly outside these ranges. Invasive scribing of the backside of wafer may not be necessary with such SHG technology. In various implementations of performing SHG measurements and SEM imaging or charge deposition with SEM components, the wafer need not be electrically grounded. To monitor charge deposition either through corona charging or SEM charging or charging with components of an SEM, the backside of the wafer can be capacitively coupled to the wafer chuck in some cases. The wafer is disposed on a wafer chuck, which may comprise metal. The backside wafer oxide remains intact, and operates like the dielectric of a capacitor. The wafer substrate operates as one electrically conductive “plate” or surface of a parallel plate capacitor and the metal chuck serves as the second “plate” of the capacitor. Capacitive coupling will allow a displacement current to flow into the chuck while charge is being deposited on the frontside. This current flowing capacitively into the chuck can be monitored with a current meter, ammeter, multi-meter, a charge meter or other electronics configured to measure the current. This current can be integrated to determine the charge deposited on the front surface. So SHG with either corona charging or SEM charging may be non-invasive and non-destructive. In other implementations, the back side of the wafer can be scribed to expose a portion of the semiconductor in the sample and a conductor (e.g., an electrode, electrical probe, or electrical contact) can be applied to the exposed portion of semiconductor. Other variations are also possible.

Scanning Electron Microscopes (SEM) have been used in the semiconductor industry for inspection. If, however, an SEM is not setup properly and/or for other possible reasons, the SEM can induce a large number of local charges on the wafer surface. Charging during while operating imaging samples with an SEM, can be an unwanted parasitic effect that presents problems for SEM imaging. This charging, however, can be advantageously exploited for use in conjunction with second harmonic generation. This unwanted artifact of the SEM can enable useful SHG analysis of semiconductor samples, even if SEM imaging is not employed. Exploiting this perceived problem of SEM imaging as an advantage in the case where charging is desired, the SEM can be used to charge a dielectric (e.g., oxide) surface rather than employing, for example, a corona gun. An SEM or SEM components can precisely place charge with high resolution. SEM resolution can be down to 1 nm, however, SEM resolution no smaller than 0.1 of the laser spot size may also be employed in various implementations. Consequently, by employing an SEM, the surface can be charged down to a measurement spot size diameter of a few nanometers, e.g., from 1 to 10 nanometers in some cases. The charge spot size when the SEM induces charging generally is the same as the SEM spot size, if there is no leakage. The charge can be controlled by adjusting the electron beam current, landing energy, and/or the scan time. Since SEMs operate in a vacuum, the dielectric (e.g., oxide) surface may have reduced surface contamination and/or moisture or be devoid of such surface contamination and/or moisture, both of which can produce a conductive/diffusive medium by which the intended surface charge laterally drifts and/or diffuses. Consequently, the SEM-based charge may remain static or have reduced movement. The charge density may be constant or close thereto, and measurement error may be reduced or minimized.

In various implementations described herein, an SEM can be used to deposit charge on a sample and a laser beam may be directed onto that sample and an SHG signal detected. In some cases, SEM imaging may be also obtained, possibly to increase accuracy of the location where charge is deposited. In other cases, SEM imaging is not obtained. In various designs where SEM imaging is not pursued, however, components of an SEM such as electron gun, anode, electron lens (e.g., condenser lens(es) and/or objective lens), vacuum chamber, vacuum pump or any subset or combination of these may be used to deposit charge and the sample may be interrogated with SHG.

Additionally, since the image quality of the SEM for charging applications may not be of particular interest in various applications, the design of the SEM can allow for long working distances, such that the laser and the SEM can access the same spot on the wafer surface without necessarily requiring a wafer move between the SEM based-charging and SHG-based (e.g., EFISH) measurements. Being able to quickly measure the response, nearly immediately following charge deposition or simultaneously during charge deposition, may also reduce any lateral diffusion of charge which may otherwise decrease charge density.

Charging of an insulating specimen or surface is the result of electron interactions with the specimen. When electrons from the SEM, referred to as primary electrons, bombard the specimen, Secondary Electrons (SEs) may be emitted in a process called secondary emission. Without subscribing to any particular scientific theory, in some circumstances the SE current minus the primary electron current determines the charging state of the specimen. Accordingly, in various implementations, the charging of the sample can be evaluated by measuring the SE yield. When the value of the SE yield is equal to one, the SE current is equal to the primary electron current, so that the specimen is neutral. When the SE yield is greater than one, the specimen should be positively charged, otherwise negatively charged. For a certain specimen material, the SE yield depends on two factors. One is the incident angle of primary electrons with respect to the normal direction of the specimen surface and the other is the energy of primary electrons.

In some implementations, SE yield can be adjusted by changing the landing energy through wafer bias changes, resulting in the deposition of either positive or negative charge.

A photomultiplier tube or other type of photodetector can be used for measurement of the SE emitted from the sample. A scintillator, for example, can be included in the path between the SEs and the photo-detector and can convert electrons incident thereon into photons that can be detected with the photodetector. In various designs, such as wherein the collector has a finite solid angle, e.g., not collecting 100% of the SE, and/or the photon multiplier is not 100% efficient, calibration can be applied to the SE signal, e.g., to increase accuracy.

An alternative way to measure the charge deposited on the wafer is to measure the current going through the wafer using a picoammeter from the back side of the wafer. However, the wafer chuck may act as an antenna and the signal-to-noise ratio may be reduced. The signal can be very small, such as less than a nanoampere (nA), and the metal chuck is like an antenna picking up electromagnetic waves resulting in noise.

The frequency response or pixel rate for an SEM is of the order of MHz while picoammeter bandwidth is of the order of a few tens of KHz.

One method of calibrating the SE detector for measuring the charging current is to image with the SEM a metallic sample where charging is not an issue. With the fixed beam current, the landing energy can be adjusted and the back side picoammeter can be measured simultaneously with the SE detector. In various implementations, beam current subtracted by the back side current is proportional to the signal from the SE detector.

In various implementations, to neutralize the charge on the wafer, the landing energy can be adjusted so that the SE yield equals one while leaving the system in this state for an extended period.

For patterned wafers where the SE yield differs as a function of varying dielectric materials, one can adjust the raster pattern of the beam, to the scan pattern of interest. Alternatively, the charging current can be measured (either by beam current minus SE or displacement current) as a function of the positioning and summing the current when on the pattern of interest. In some cases, this step may be performed as post-processing and the area not of interest may be masked out.

In general, charge rate is dependent on the SE yield as well as the beam current. To have better charge control, the SE yield can be set to 1 or proximal thereto.

When the beam current is changed, the beam spot size might change, which can potentially be at least partially offset or fully offset by a change in focus. Therefore, in some implementations, the charge amount is not set by changing the beam current.

In various implementations, during charging, the scan rate or the total number of frames can be adjusted to control the total amount of charge deposited onto the wafer. In some such cases, the beam current can be kept constant or close thereto.

In various implementations, the lateral position accuracy of the electron beam is on the order of nanometers. Controlling the SEM scanning area with sufficient precision may reduce or avoid charging other unrelated patterns, structures, devices, etc. nearby that might create parasitic electric fields, which may result in interference with the SHG measurement.

Even in vacuum, when there is no air, charge disposed on the wafer can still diffuse laterally due to a large potential difference. To prevent or reduce the incidence of this lateral diffusion, a perimeter (e.g., a ring) of opposite charge can be deposited as a guard, guard ring or guard region.

Apart from charging the wafer, the SEM can also be used as a microscope. Accordingly, in various implementation, the SEM may be employed to precisely charge the area of interest.

The present invention will best be understood from the following description of specific embodiments when read in connection with the accompanying drawings.

### BRIEF DESCRIPTION OF THE DRAWING

FIG. 1 is a view of a vacuum chamber with an electron beam source therein, the electron beam source in position with respect to the wafer surface to direct electrons thereto; a secondary electron detector in the vacuum chamber and positioned to receive secondary electrons from the sample; and an SHG or EFISH interrogating laser source positioned with respect to an optical window to direct light into the vacuum chamber; and an SHG or EFISH detector in proximity to the wafer surface to receive second harmonic generation (SHG) light from the sample.

FIG. 2 is a view of the electron beam source within the vacuum chamber, in position with respect to the wafer surface to direct electrons thereto; the secondary electron detector positioned to receive secondary electrons from the sample; the interrogating laser source directing light into the vacuum chamber via a vacuum fiber feedthrough; and an electron detector in proximity to the wafer surface to receive SHG light from the sample.

FIG. 3 is a schematic view of a charge measurement region surrounded by a guard ring or region of the opposite polarity charge as the measurement region.

FIG. 4 is a plot on axis of SHG signal (arbitrary units) and electron beam charge (arbitrary units) of SHG signal obtained for varying levels of net electron beam charge on the surface of sample. The plot includes a set of two SHG versus net e-beam charge curves: one with the effects of interface state density and one without. A first SHG curve 24 represents the actual SHG versus charge curve just measured. The reference curve 22 represents an SHG versus charge curve from a reference sample that has extremely low interface state density (Dᵢₜ), or a theoretical SHG versus charge curve, with zero interface state density, which is obtained from modeling. The difference between the two curves 22, 24 can represent deviation from ideal due to interface state density (Dᵢₜ).

### DETAILED DESCRIPTION

As discussed in the U.S. Patent Publication No. 2015/0330909 titled “WAFER METROLOGY TECHNOLOGIES” published on Nov. 19, 2015, which is incorporated herein by reference in its entirety, second harmonic generation may be employed to obtain information regarding properties of a sample such as a silicon wafer. A metrology system for obtaining measurements of the sample may include a laser that outputs light that is directed onto the sample and an optical detector that received light reflected from the sample. This light reflected from the sample may comprise a second harmonic generation signal that can be analyzed with electronics to obtain information regarding the sample.

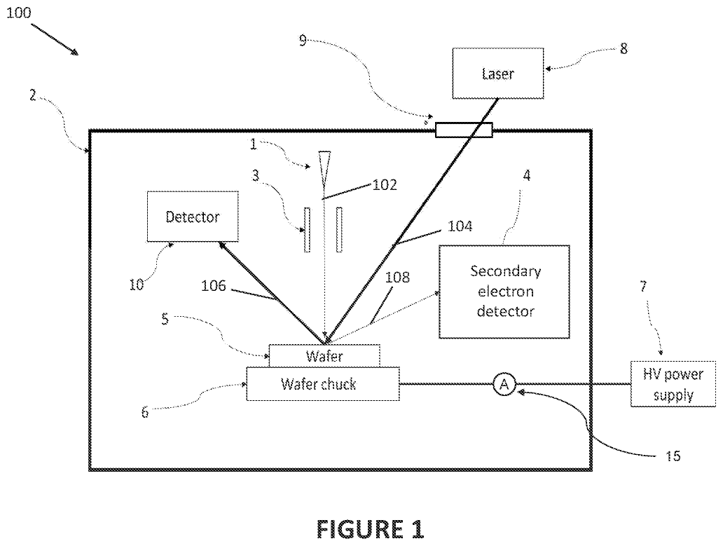

Referring now to FIG. 1, an apparatus 100 for interrogating a sample 5, such as a semiconductor wafer, may comprise the components of a scanning electron microscope (SEM) and additionally include a second harmonic generation (SHG) system. Likewise, the apparatus 100 for interrogating the sample 5 may comprise an electron gun 1, an anode (not shown) and electron optics 3 inside a vacuum chamber 2, components that are generally employed to construct an SEM. The electron gun 1 emits electrons, which are attracted to the anode, which is generally a positively charged disc or plate. The electric field provided by the anode accelerate the electrons to the anode. The anode can have a hole through which the electrons pass onto the electron optics 3. The electron optics 3 may comprise one or more electron lenses. These lenses may comprise condenser lenses and/or an objective lens that may focus the beam to a smaller lateral dimension.

Electron apertures may precede one or more of the lenses. The electron optics may further comprise an electron beam deflector, which may comprise one or more coils or conductors to selectively carry current and produce a magnetic field that exerts forces on the electrons traveling by to the sample. The coils are arranged and/or oriented to push the electrons or electron beam in different lateral directions.

Accordingly, in operation the electron gun 1 generates the electrons and the column has a high electric field possibly applied by the anode that accelerates the electrons in the electron beam towards the sample, e.g., the wafer, 5 while the electron beam is acted upon by electron optics 3 situated in proximity thereto as the beam progresses through the “column” and electron optics. As stated above, after the condenser lens(es), such electron optics 3 may comprise one or more deflection or scanning coils through which the electron beam 102 passes.

As discussed above, the electron optics 3 may comprise one or more lenses to focus the electrons in the electron beam. The electron lens(es) may comprise magnets or coils that can carry current to produce a magnetic field that can cause the electrons to converge. The lenses can include one or possibly a plurality of condenser lenses.

Additionally, as discussed above, the beam deflectors in the column comprising separate conductors such as coiled wire arranged on different sides of the electron beam 102 to move the beam laterally in a variety of directions. The current can be directed through the conductors to selectively generate a magnetic field on a side of the beam to move the beam in a suitable direction to the target area of the sample. In this manner, the beam can be scanned such as raster scanned or moved to specific target location on the sample.

The lenses may also include an objective lens closer to the sample than the other lenses. Accordingly, the electron optics 3, e.g., column, focuses and deflects the electron beam 102 thereby providing for a spot of electrons incident on the sample 5 with the position of the spot movable by suitable deflection of the electrons provided by the deflection or scanning coils 3. A secondary electron detector 4 may also be included inside the chamber 2 to collect the secondary electrons coming from of the wafer 5. The scanning or deflection coils in the column 3 can raster the electron beam 102, thereby causing the electrons collected from the secondary electron detector 4 to form an image of the sample 5. In some implementations, this image can be employed to locate a patterned semiconductor structure to be interrogated, the pattern under test, on the sample 5 or other region of the sample to be interrogated. Accordingly, in some implementations, the SEM components form an SEM that can be used to image. In other implementations, the components such as electron gun 1, anode, and electron optics are not configured to produce images from the secondary electrons but may be used to deposit charge on the sample, which can be interrogated optically using, for example, SHG light.

The wafer 5 is positioned on top of a wafer chuck 6. In some implementations, the wafer chuck 6 has a sharp pin on the top that punches through the backside oxide on the wafer 5 to provide an electrical contact to the wafer. This electrical contact may be electrically connected to a pico-ammeter or other electronics 15 configured to measure the current and/or charge or other electrical parameter. In some alternative configurations, instead of having a sharp pin contact the backside of the wafer, the wafer could also be capacitively coupled. As described above, the oxide need not be removed and may operate as a dielectric between two conducting surfaces: doped semiconductor of the sample and the conductive surface of the sample holder on which the wafer rests. The sample need not be grounded in such a capacitively coupled configuration.

A “displacement current” will flow to counterbalance the capacitor. This displacement current can be measured and integrated to determine the amount of charge deposited on the sample and/or the amount the sample is charged.

In either case, an ammeter or current meter or other configuration for measuring current can be included. The flowing picoammeter 15 may be used to measure the charging current and to calibrate the secondary electron detector 4. A high voltage supply 7 can establish a voltage on the wafer chuck 6, in some configurations, through the flowing picoammeter 15 to control the landing energy of the electron beam 102. The landing energy can control the SE yield and therefore how much charge is deposited on the sample 5 and/or how much the sample is charged.

In more detail, still referring to the invention of FIG. 1, a laser source 8 such as a pulsed laser source like a femtosecond laser, is located outside the chamber 2. The probe light 104 from interrogating laser 8, such as a laser pulse having a pulse width, goes through a vacuum view window 9 before being incident on the wafer 5. In various implementations, the vacuum view window 9 should not change the pulse width of optical or laser pulses from the interrogating laser 8. An SHG detector 10 is located inside the chamber 2 to detect the second harmonic signal generated 106 (although in some implementations the SHG detector could be outside the vacuum chamber.) FIG. 1 is a view of the electron beam source 1, in position with respect to the wafer 5 or wafer surface to deposit charge on the wafer or wafer surface. FIG. 1 also shows the secondary electron detector 4 positioned so as to receive secondary electrons 108 emitted from the sample 5. Additionally, FIG. 1 show the laser source 8 (e.g., SHG or EFISH laser source) in position with respect to the wafer 5 or wafer surface to direct the probe laser beam 104 onto the wafer and the optical detector 10 (e.g., SHG or EFISH detector), an optical sensor such as a photovoltaic or photoconductor or photomultiplier tube, in proximity to the wafer surface to receive the SHG light 106 from the sample.

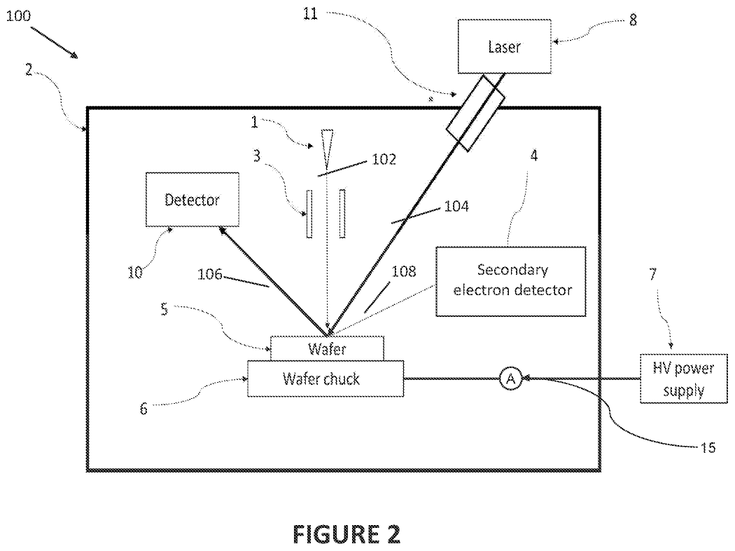

Referring to FIG. 2, in various implementations such as shown, the interrogating laser beam 104 enters the vacuum chamber 2 via a vacuum fiber feedthrough 11 comprising an optical fiber.

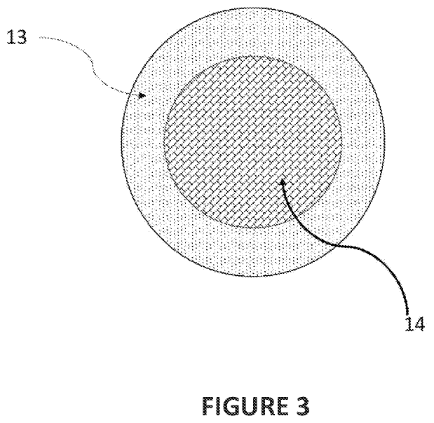

Referring to FIG. 3, to prevent charge from diffusing laterally, e.g., for SHG applications directed to charge carrier lifetime measurements, a guard ring or guard region 13 comprising charge can be deposited on the wafer 5, while charge of opposite polarity is deposited on an inner region 14 inside the guard ring or region. Positive charge is deposited over the inner region 14 for p-type semiconductors and negative charge for n-type. First, the initial charge for the inner region 14, drives the underlying semiconductor into a state of depletion as free carriers are repelled and depleted from the interface region. Additional charge over inner region 14 then drives the semiconductor region into a state of inversion, which is an analog to what happens in a MOSFET transistor channel when a voltage is applies to the metal gate. The area of the sample 5 to be interrogated by SHG light 106, e.g., the area of the sample illuminated by the probe laser beam 104 from the laser source 8, may be within this inner region 14. In addition, a pump light source with energy greater than the bandgap of the semiconductor under test, can be used to excite electron-hole pairs in the semiconductor region 14 can be used. The guard ring 13 comprises charge having opposite polarity to the charge in the inner region 14 inside the guard ring 13.

The guard ring 13 charge images itself in the semiconductor with opposite sign charge forming within the semiconductor on an opposite side of the surface as the deposited charge. Carriers within the semiconductor are produced in response to the type of charges deposited on the oxide. In various implementations, the semiconductor surface under the outer (e.g., guard ring) region 13 is in a state called accumulation. This accumulated majority carrier charge within the semiconductor serves as a guard because the majority carrier charge in the semiconductor beneath the ring 13 and the inversion charge beneath the inner region 14, form a p-n junction parallel to the oxide semiconductor interface. Because all p-n junctions have a built-in potential (and electric field) and because the polarity of this built-in potential opposes minority carrier charge generated under the inner region 14 by the pump source, carriers remain confined to inner region 14 until they can recombine with their charge carrier counterparts. Minority carrier charges in the semiconductor, e.g., free carriers (e.g., generated by the optical pump), under region 14, would be inclined to drift/diffuse laterally within the semiconductor, but instead, get repelled by the built-in potential of the underlying p-n junction formed by the accumulation guard ring under 13 and the inversion layer under region 14.

Once the underlying surface in the semiconductor under the guard ring 13 is in accumulation, and the underlying region in the semiconductor for region 14 is in inversion, the semiconductor surface is prepared to be tested. A test is subsequently performed when pump [light source excites carries under region 14, and the SHG light 106 is used to observe the response.

To form the guard ring, charge having a first polarity is deposited on the surface of the sample, for example, on an insulator (e.g., oxide) layer formed on semiconductor (e.g., silicon), over a first area, which in this example has a shape of a circle or disc. An SEM or arrangement of SEM components such as described above (e.g., electron gun, anode, electron lens(es), electron beam or e-beam deflector, vacuum chamber, vacuum pump, etc.) can be used to deposit the charge over the appropriate location, e.g., within the boundaries of the first area. Scanning and depositing charge can facilitate deposition of a suitably shaped pattern of charge. In this example, the distribution of charge (with radial distance from the center) may have a “tophat” shaped profile. The footprint may be circular. The diameter of this first disc may define the outside diameter of the annular guard region 13 shown in FIG. 3. The charge can be constant and uniformly distributed and can have the same polarity over the entire disc. Subsequently, charge of a second polarity opposite to that of the first is deposited on the surface of the sample, for example, on an insulator layer (e.g., oxide) formed on semiconductor (e.g., silicon), over a second area, which in this example has a shape of a circle or disc and diameter of region 14. This second area, which is circularly shaped is smaller (e.g., has a smaller diameter) than the first region, which is also circularly shaped. The second polarity of the charge deposited is the opposite of the first polarity. Additionally, the first and second areas overlap. In this example, the second area fits within the first area. The charge in the second area (second disc) is deposited over the first area (first disc). In this example, the first and second regions have a common center (e.g., are concentric) and are both circular regions. Where the first and second regions (discs) overlap, the charge already in the first region due to the first deposition initially gets neutralized, then flipped in sign to the concentration needed for the test region 14 of FIG. 3. The result is the outer annular region 13 having the first polarity and the inner second region 14 having the second opposite polarity.

Although the charge in regions 13 and 14 have opposite polarities, which in general attract, the lateral “conductivity” for these charges moving across the oxide surface to annihilate one another is low. Some nulling of charge does occur, but in general, the positive and negative charges on the insulator (e.g., oxide) surface remain separated, especially if deposition is performed in a vacuum and the sample remains in vacuum. Water on the oxide surface can increase conductivity and lead to the charge nulling. However, vacuum mitigates against the presence of the moisture on the surface.

In various implementations, free majority carriers gather in the semiconductor under the guard ring 13. Under the central test region 14, for initial packets of charge, the semiconductor may be generally devoid of free carriers forming a depletion region. Eventually, if enough charge is deposited, an inversion region is formed and composed of minority carriers. For a p-type semiconductor, minority carriers would be electrons. For example, for the guard ring 13, for a p-type semiconductor where free carriers are positively charged holes and few negative free charges (i.e., electrons) exist, if negatively charged electrons are deposited on the insulator (e.g., oxide) by the electron beam for the guard ring, these positive holes will accumulate in the semiconductor beneath the insulator (e.g., oxide) in response to the deposited negatively charge electrons. A ring of positive free carriers will be formed adjacent to the semiconductor/insulator (e.g., silicon oxide) interface.

For the test region 14, the electron gun, anode, and other components controlling the electron beam 102 are configured to deposit positive charge for a p-type underlying semiconductor. (The charge polarities for regions 13 and 14 would be opposite for an n-type semiconductor.). Again for p-type, the positive charge on the surface of the test region 14, for example, on the insulator (e.g., oxide) repels the positively charged free carries in the semiconductor (e.g., silicon) beneath away from the interface insulator semiconductor interface. In this example where the semiconductor is doped p-type, the negative charge in the semiconductor comprises uncompensated p-type dopants. This area may be referred to as a depletion region. The semiconductor in this area is in a state referred to as depletion. The positive electron beam deposited charge near the center is balanced by the negatively charged stationary dopant (e.g., boron) atoms, and if enough charge is deposited, the uncompensated dopants (depletion region) and an inversion layer of electrons. In contrast, under the guard ring 13, the semiconductor is in a state referred to as accumulation, with an accumulation of positive holes.

Although the holes under the guard ring 13 are coulombically attracted to the laterally positioned negatively charged dopants (e.g., boron dopants), this concentration of holes on average remains in the guard ring to satisfy Gauss's law with the negative deposited electrons on the surface. Additionally, the positive charge above the space charge region would repel flow of positive charge toward the test region 14.

Accordingly, in the test region 14, the semiconductor surface has a negatively charged space charge region (depletion region) devoid of free majority carriers and the guard ring 13 comprises accumulated holes. Consequently, when the SHG probe pulse of light having energy that exceeds the bandgap of the semiconductor is incident on the semiconductor in the test region 14, electron-hole pairs are produced in the space-charge or depletion region. An electric field in the depletion region is produced that attracts the excess electrons to the interface and forces the holes out of the region. In various measurements, how quickly this packet of electrons recombines with hole may be observed and/or measured and, for example, the amount of defects can be assessed. Excess electrons and holes recombine via defects in the semiconductor. Higher recombination occurs with more defects. The electrons are restricted from moving laterally out of the test region 14 by repulsive forced from the p-n junction built-in potential parallel to the oxide/semiconductor interface. The rate of decay of electrons recombining with holes by way of interaction with defects can be measured.

The guard ring 13 as well as the inner charged region 14 can be any shape and need not have circular boundaries. Similarly, the outer perimeter of the guard ring 13 need not have the same shape as the outer perimeter of the inner charged region 14 although in certain implementations, the shape of both the inner and outer perimeters of the guard ring are the same as the shape of the inner charged region 14. In various implementations, the guard ring 13 is slightly larger than the inner charged region 14. However, the sizes (as well as the shapes) of both the guard ring 13 and the inner charged region 14 can be different than shown in FIG. 3.

As discussed above, in some implementations, the measurement is referred to as contactless because electrical contact with the front-side of the wafer is not required. For product wafer, semiconductor devices are present on the front-side, however, charge is deposited by directing a beam of electrons onto the front surface, not by providing an electrical contact to the front side. Similarly, current flow need not be measured by applying a contact to the front side of the wafer. Accordingly, various approaches described herein are non-contact and not invasive with regard to the front-side of the wafer. In contrast, some other approaches may either involve contacting the frontside or are invasive or destructive to the front side in some way. Such approaches may encounter limits in testing product wafers. Such technologies utilize, instead, monitor or test wafers. In contrast, various implementations described herein are non-contact and non-invasive from the frontside as charge is applied from a distance by directing an electron beam 102 onto the surface of the sample (e.g., wafer) and SHG measurements are optical non-contact measurements involving directing the probe laser beam from a probe laser onto the surface of the wafer and collecting SHG light propagating from the wafer using an optical detector, both the probe laser and optical detector positioned a distance away from the wafer.

Some sort of backside contact may be made, for example, through a wafer chuck, which holds the wafer. In various implementations, the chuck or sample holder is non-invasive, non-contaminating, non-destructive and the measurement techniques do not involve damaging contact or contamination to the front side of the wafer. Current measurements may be performed using capacitive coupling through the backside of the wafer. For example, displacement current can be measured using capacitive coupling where doped semiconductor on the wafer comprises a first conductive region, and the conducting (e.g., metal) sample holder or chuck comprises the second conductor separated from the first conductor by an insulator or dielectric such as oxide like silicon oxide. An ammeter or other electronics configured to perform current measurement may be electrically connected to the conductive sample holder, e.g., may be in electrical contact with the conductive surface of the chuck or sample holder on which the sample rests and/or makes contact. The displacement current may thus be measured. Accordingly capacitive coupling can be used to measure the current from the back side and non-contact optical measurements can be performed from the front side. As a result, for such designs, measurements may be made on product wafers as damage to the wafer front-side or backside, can be avoided. However, in other implementations, the backside of the wafer can be modified, for example, insulator (e.g., oxide) can be removed in an area and a conductive probe or needle can make contact with exposed semiconductor (e.g., silicon) or other layers. The probe or needle can be electrically connected to an ammeter or electronics for measuring current, and the charging current can be measured.

The SHG light 106 can be measured for different amount of charge deposited on the sample and/or charging of the sample. In some implementations, this information may be used to determine the density of traps or other states such as the density of interface states. Likewise, in various implementations, electronics are included in the apparatus 100 to control. e.g., vary, and/or monitor the amount of charge deposition and/or charging and to measure the SHG light 106 for different amount of deposited charge and/or charging. In various implementations, the electronics may determine a density of states such as interface states based on the measured variation of the SHG light 106 with variation in charge deposition and/or charging of the sample. The electronics may, for example, compare the variation of the SHG light 106 with variation in charge deposition and/or charging to stored variations or based on a model of variation SHG signal with variation in charge deposition and/or charging or otherwise make a comparison or determine (e.g., calculate or estimate) density of states from the variation in SHG light.

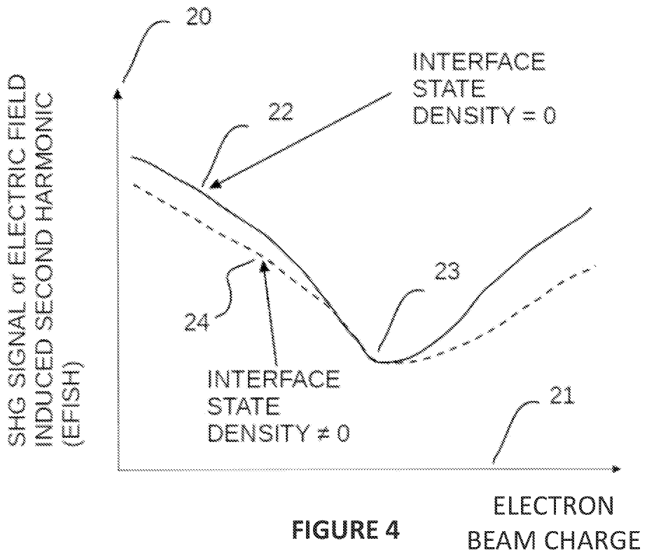

Likewise, various metrology systems described herein can advantageously be employed to determine the total charge (or net charge) trapped in an oxide on a semiconductor like silicon due to defects (Qₜₒₜ). This measurement can be obtained by observing the variation of the second harmonic generation signal with applied electron beam charge. FIG. 4 is a plot of EFISH 20 versus net electron beam charge on the surface of the sample 21; see, e.g., curve 24. The total charge or net charge trapped in the oxide due to defects, Qₜₒₜ, can be determined from the point on the EFISH 20 versus net electron beam charge on the sample 21 curve 24 with low second harmonic generation signal, e.g., at the “position” 23. Curve 24 shows the dependency of EFISH on variation of net electron beam charge 21 for the case where the interface state density (Dᵢₜ) is not zero but is significant in causing distortion of the second harmonic generation signal and the EFISH versus charge curve and is significant in contributing interface state charge (Qᵢₜ) to the total charge Qₜₒₜ. In certain implementations, to determine the total charge in the oxide, electron beam charge is deposited on the surface of the dielectric on the semiconductor sample and the EFISH signal is monitored until the EFISH reaches its low or minimum, 23. At this point, the net charge 21 applied to produce the low or minimum 23 is equal to the magnitude of Qₜₒₜ, and negative to the total charge, −Qₜₒₜ, in polarity. Dᵢₜ simply gives rise to some trapped charge that contributes a component of Qₜₒₜ. Qₜₒₜ is the total charge in the oxide. This charge occurs through defects in the oxide, and at the oxide/semiconductor interface (Dᵢₜ). This charge, Qₜₒₜ, in the oxide, images itself through Gauss's law in the semiconductor surface as −Qₜₒₜ. To achieve the −Qₜₒₜ, a potential develops in the semiconductor surface which has polarity and increases the SHG response. The production and effect of this potential is often referred to as “band bending”. To measure Qₜₒₜ, enough charge is deposited on the oxide surface through the electron beam to achieve −Qₜₒₜ on the oxide surface. When −Qₜₒₜ is obtained, the drive for the oxide Qₜₒₜ to image itself in the semiconductor dissipates. Qₜₒₜ is now imaging itself on the oxide surface through −Qₜₒₜ that was deposited. When this state is achieved, a minimum 23 in the SHG versus corona charge curve 24 can be observed.

Additionally, the interface state density, Dᵢₜ, can be determined by comparing the EFISH 20 versus electron beam charge 21 curve 24 of the sample under test, with significant Dᵢₜ to distort the curve, with an EFISH versus electron beam charge curve 22 that is experimentally obtained for a like sample that has very low Dᵢₜ. As discussed above, the two curves represent the sample under test with presumably significant Dᵢₜ, 24, and a curve from either a low-Dᵢₜ reference sample, or a theoretical SHG versus electron beam charge 22 for low-Dᵢₜ generated using a theory based model.

An EFISH 20 versus net electron beam charge 21, curve 22 for a like sample that has very low Dᵢₜ can be obtained by modeling based EFISH versus net electron beam charge on the sample that excludes any contribution from Dᵢₜ, but includes other forms of contribution, possibly all forms of contributions, to the EFISH versus net electron beam charge curve. The difference between the two curves 24 and 22, yield the interface state density of varying positions along the electron beam charge 21 axis.

Advantages of the apparatus 100 described herein include, without limitation, systems for performing electron beam (Ebeam) wafer surface charging and measuring the EFISH response with the Ebeam bias present without making a wafer move between charging and EFISH measurement. Not moving the wafer can speed up the process and may result in less charge diffusion and/or dissipation during an SHG measurement. Since an SEM based Ebcam source operates in a vacuum, the oxide/dielectric surface may have reduced or be devoid of surface contamination and/or moisture (both of which can provide a conductive/diffusive medium with corona based charging) by which the intended surface charge laterally drifts and diffuses. Consequently, the SEM-based charge may remain static or travel a reduced amount, the charge density may remain constant or change by a reduce amount, and measurement error may be reduced or minimized.

Accordingly, various implementations may comprise a system for precisely controlling charge deposition for semiconductor wafer testing, and more particularly, may provide a non-contact, non-invasive method for testing such wafers.

While the foregoing written description of the invention enables one of ordinary skill to make and use what is considered presently to be the best mode thereof, those of ordinary skill will understand and appreciate the existence of variations, combinations, and equivalents of the specific embodiment, method, and examples herein. The invention should therefore not be limited by the above-described embodiment, method, and examples, but by all embodiments and methods within the scope and spirit of the invention.

### Example Embodiments

Example embodiments described herein have several features, no single one of which is indispensable or solely responsible for their desirable attributes. A variety of example systems and methods are provided below.

### Group 1

Example 1. A contactless, non-invasive, and ungrounded measurement method for testing a doped wafer with an insulator layer disposed thereover, comprising:
depositing charges on the top surface of said insulator layer using an SEM Ebeam, the resultant accumulated, depleted and/or inverted semiconductor surfaces in the wafer,
measuring the resultant Electric Field Induced Second Harmonic (EFISH),
producing an EFISH versus SEM based charge density curve spanning the semiconductor surface accumulation state to the semiconductor inversion state; and
calculating the interface state density based on a comparison between the shape of the measured EFISH versus SEM charge curve and a mechanistically modeled EFISH versus SEM based charge curve.

Example 2. The method as defined in claim 1, wherein said mechanistically modeled EFISH versus Ebeam charge curve, does not include a mechanism or component attributed to the interface state charge.

Example 3. The method of claim 2, wherein the difference between the experimentally acquired EFISH versus SEM charge curve and the mechanistically modeled EFISH versus SEM charge curve, provides the information needed to calculate the interface state density (Dᵢₜ).

Example 4. A method as defined in claim 1, wherein said EFISH versus SEM charge curve is acquired from within a vacuum chamber.

Example 5. The method of claim 4 that reduces lateral drift and diffusion of deposited charge by reducing organics, inorganics, and/or water from the wafer surface.

Example 6. A method of depositing charge with an SEM and measuring the EFISH response comprised of: a large working distance EFISH probe allowing for SEM based charging; and resultant EFISH measurement at the same measurement site without a semiconductor wafer move. The working distance of the SEM or SEM components (e.g., electrode, anode, electron lens(es) and electron beam deflector) can be 5 mm or more. One consideration is that the SEM components, such as the objective lens not be so close to the sample or chuck that it blocks the laser probe beam incident on the sample to provide SHG as well as having sufficient room to collect the SHG light. This working distance can be measured from the objective lens of the SEM. For example, the working distance of the electron lens comprising the objective may be 5 mm or more. Or the distance of the element (e.g., element on the SEM) closest to the sample or surface of the sample holder (e.g., chuck) on which the sample is positioned may be 5 mm or more.

Example 7. The method of claim 1, whereby charging of an insulating specimen or surface is the result of the electron interaction with the specimen, such that the Secondary Electrons (SEs) current minus the primary electron current (SE yield) determines the charging state or polarity of charge on/in the specimen.

Example 8. The method of claim 7 such that when the value of the SE yield is equal to one, the SE current is equal to the primary electron current, so that the specimen is neutral.

Example 9. The method of claim 7 such that when the SE yield is greater than one, the specimen will be positively charged.

Example 10. The method of claim 7 such that when the SE yield is less than one, the specimen will be negatively charged.

Example 11. A method of measuring or calibration of the SEM-based charge magnitude and sign, using a coulomb meter electrically connected to a wafer chuck, upon which the semiconductor wafer is positioned.

### Group 2 (SEM)

Example 1. A system for optically interrogating a sample accompanied by the application of electric charge to said sample, said system comprising:
a. an electron beam generation and scanning system comprising an electron gun, an anode, at least one electron lens, and an electron beam deflector disposed with respect to the sample to direct electrons to the sample to place charge on the sample;
b. a vacuum system comprising a vacuum chamber and a vacuum pump, said electron gun, said anode, said at least one electron lens, said electron beam deflector and said sample included in said vacuum chamber,
c. a probe optical source configured to emit probing light, said probe optical source disposed so as to direct said probe light onto said sample; and
d. an optical detector configured to detect second harmonic generated light from the sample in response to said probe light directed thereon.

Example 2. The system of Example 1, wherein said at least one electron lens comprises an objective.

Example 3. The system of Example 1, wherein said scanning electron microscope has a work distance of no less than 5 millimeters (mm).

Example 4. The system of any of the Example above, further comprising an electron detector in said chamber.

Example 5. The system of any of the Examples above, wherein said probe optical source comprises a pulse laser and said optical detector comprise a photovoltaic, a photoconductor, or a photomultiplier tube.

Example 6. The system of any of the Examples above, wherein said vacuum chamber has a window or fiber feedthrough for transmission of said probe light into said chamber.

Example 7. The system of any of the Examples above, further comprising a chuck for supporting said sample.

Example 8. The system of Example 10, further comprising an ammeter electrically connected to said chuck to measure charge flow from said chuck.

Example 9. The system of Example 10 or 11, further comprising a high voltage source electrically connected to said chuck to apply a voltage to said sample.

Example 10. The system of any of the Examples above, wherein said electron beam generation and scanning system comprises a scanning electron microscope (SEM).

Example 11. The system of any of the Examples above, further comprising electronics configured to receive an electronic signal from said optical detector.

Example 12. The system of any of the Examples above, wherein said electronics are configured to determine a characteristic of the sample based on the detected SHG light.

Example 13. The system of any of Examples 11-12 wherein said electronics are configured to determine a characteristic of the sample based on the variation in the detected SHG light.

Example 14. The system of any of Examples 11-13 wherein said electronics are configured to determine a characteristic of the sample based on the variation in the detected SHG light with different amount of electrical charge deposited on or in the sample and/or the charging of the sample.

Example 15. The system of any of Examples 11-14, wherein said electronics are configured to receive an electronic signal from said optical detector to determine a characteristic based on said SHG light.

Example 16. The system of any of Examples 11-15, wherein said electronics are configured to monitor the SHG signal for varying amounts of charge deposited on or in the sample by the electron beam generation and scanning system and/or for varying amounts of charging of the sample by the electron beam generation and scanning system.

Example 17. The system of any of Examples 11-16, wherein said electronics are configured to estimate a density of states based on said SHG signal.

Example 18. The system of any of Examples 11-17, wherein said electronics are electrically connected to said electron beam generation and scanning system and configured to form a guard region with charge having a first polarity and an inner region surrounded by said guard region having a second polarity having opposite said first polarity on said sample.

Example 19. The system of Example 18, wherein said electronics and said electron beam generation and scanning system are configured to form said guard region and said inner region by depositing charge of said first polarity over a larger region and depositing charge of a second polarity over a smaller region within said larger region such that said guard region surrounds said inner region.

Example 20. The system of Example 18 or 19, wherein if said sample comprises p-type semiconductor, said first polarity is negative and said second polarity is positive.

Example 21. The system of any of Examples 18-20, wherein if said sample comprise n-type semiconductor, said first polarity is positive and said second polarity is negative.

Example 22. The system of any of Examples 11-21, wherein said electronics are configured to estimate a density of states of the sample based the variation in SHG signal with different amount of electrical charge deposited on or in the sample and/or the charging of the sample.

Example 23. The system of any of Examples 11-22, wherein said electronics are configured to estimate an interface state density based on a comparison between (a) the dependency of the measured SHG versus charge deposited and (b) a modeled dependency of SHG versus deposited charge.

Example 24. The system of any of Example 11-23, wherein said electronics are configured to estimate an interface state density based on a comparison between (a) the dependency of the measured SHG versus charge deposited and (b) a stored dependency of SHG versus deposited charge.

Example 25. The system of any of Example 11-24, wherein said electronics are configured to estimate an interface state density based on a comparison between (a) a dependency of the measured SHG versus charge deposited and (b) a dependency of SHG versus deposited charge for a system having less states.

Example 26. A method of optical interrogation of a sample, the method comprising:
a. applying probing radiation from a probing optical source to the sample;
b. depositing electrical charge on or in the sample and/or charging the sample using an electron beam generation and scanning system comprising an electron gun, an anode, at least one electron lens, and an electron beam deflector disposed with respect to the sample to direct electrons to the sample to place charge on the sample;
c. detecting using an optical detector, Second Harmonic Generation (SHG) effect light generated by the probing radiation for the electrical charge deposited on or in the sample and/or charging of the sample.

Example 27. The method of Example 26, further comprising determining a characteristic of the detected SHG effect light based on the electrical charge deposited on or in the sample and/or charging of the sample.

Example 28. The method of Example 26 or 27, further comprising
a. varying the amount of charge deposited on or in said sample and/or the charging of the sample; and
b. detecting using said optical detector, a variation in the Second Harmonic Generation (SHG) light generated by the varying amounts of charge and/or charging.

Example 29. The method of Example 28, further comprising determining a characteristic of the sample based on the variation in the detected SHG light with different amount of electrical charge deposited on or in the sample and/or the charging of the sample.

Example 30. The method of Example 28 or 29, further comprising estimating a density of states of the sample based the variation in SHG signal with different amount of electrical charge deposited on or in the sample and/or the charging of the sample.

Example 31. The method of any of Examples 28-30, further comprising forming a guard region with charge having a first polarity and an inner region surrounded by said guard region having a second polarity having opposite said first polarity.

Example 32. The method of any of Examples 28-31, wherein said electron beam generation and scanning system comprises a scanning electron microscope (SEM).

Example 33. The method of Example 32, further comprising imaging the sample with the SEM.

Example 34. The method of any of Examples 28-33, further comprising estimating an interface state density based on a comparison between (a) the dependency of the measured SHG versus charge deposited and (b) a modeled dependency of SHG versus deposited charge.

Example 35. The method of any of Examples 28-34, further comprising estimating an interface state density based on a comparison between (a) the dependency of the measured SHG versus charge deposited and (b) a stored dependency of SHG versus deposited charge.

Example 36. The method of any of Examples 28-35, further comprising estimating an interface state density based on a comparison between (a) a dependency of the measured SHG versus charge deposited and (b) a dependency of SHG versus deposited charge for a system having less states.

Example 37. The method of any of Examples 28-36, further comprising exposing said sample to pump radiation.

Example 38. The method of Example 37, further comprising using a laser or lamp to provide said pump radiation.

Example 39. The system of any of Example 1-25, further comprising an optical pump configured to expose said sample to pump radiation.

Example 40. The system of Example 39, wherein said optical pump comprises a laser or lamp.

### Group 3 (Density of States)

Example 1. A method of optical interrogation of a sample, the method comprising:
applying probing radiation from a probing optical source to the sample;
depositing electrical charge on or in the sample and/or charging the sample;
detecting using an optical detector, Second Harmonic Generation (SHG) effect light generated by the probing radiation for the electrical charge deposited on or in the sample and/or charging of the sample;
varying the amount of charge deposited on or in said sample and/or the charging of the sample;
detecting using said optical detector, a variation in the Second Harmonic Generation (SHG) light generated by the varying amounts of charge and/or charging; and
estimating an interface state density based on a comparison between (a) a first dependency of SHG versus charge on the surface of the sample and (b) a second dependency of SHG versus charge on the surface of the sample, wherein said first dependency comprises measured SHG versus charge.

Example. 2 The method of any of the claims above, wherein said estimating an interface state density is based on a comparison between (a) the dependency of the measured SHG versus charge deposited and (b) a modeled dependency of SHG versus deposited charge.

Example. 3 The method of any of the claims above, wherein estimating an interface state density is based on a comparison between (a) the dependency of the measured SHG versus charge deposited and (b) a stored dependency of SHG versus deposited charge.

Example 4. The method of any of the claims above, wherein estimating an interface state density is based on a comparison between (a) a dependency of the measured SHG versus charge deposited and (b) a dependency of SHG versus deposited charge for a sample having less states.

Example 5. The method of any of the claims above, wherein said estimating an interface state density is based on a comparison of (a) the shape of a first curve of SHG versus charge on the surface of the sample and (b) the shape of a second curve of SHG versus charge on the surface of the sample, wherein said first curved comprises measured SHG versus charge.

Example 6. The method of any of the claims above, further comprising forming a guard region with charge having a first polarity and an inner region surrounded by said guard region having a second polarity opposite said first polarity.

Example 7. The method of Claim 6, wherein said probing radiation is directed to said inner region surrounded by said guard region.

Example 8. The method of any of the claims above, wherein said charge is deposited by an electron beam generation and scanning system comprising an electron gun, an anode, at least one electron lens, and an electron beam deflector disposed with respect to the sample to direct electrons to the sample to place charge on the sample.

Example 9. The method of any of the claims above, wherein said charge is deposited by a scanning electron microscope (SEM).

Example 10. The method of Claim 9, further comprising imaging the sample with the SEM.

Example 11. A system for optically interrogating a sample accompanied by the application of electric charge to said sample, said system comprising:
an electrode configured to place charge on the sample, said electrode spaced apart from the sample;
a probe optical source configured to emit probing light, said probe optical source disposed so as to direct said probe light onto said sample;
an optical detector configured to detect second harmonic (SHG) generated light from the sample in response to said probe light directed thereon; and
electronics configured to vary the amount of charge deposited on or in said sample and/or the charging of the sample such that said optical detectors detects a variation in the Second Harmonic Generation (SHG) light generated by the varying amounts of charge and/or charging; and
said electronics configured to estimate an interface state density based on a comparison between (a) a first dependency of the SHG versus charge on the surface of the sample and (b) a second dependency of SHG versus charge on the surface of the sample, wherein said first dependency comprises measured SHG versus charge.

Example 12. The system of Claim 11, wherein said electronics are configured to estimate an interface state density based on a comparison between (a) the dependency of the measured SHG versus charge deposited and (b) a modeled dependency of SHG versus deposited charge.

Example 13. The system of Claim 11 or 12, wherein said electronics are configured to estimate an interface state density based on a comparison between (a) the dependency of the measured SHG versus charge deposited and (b) a stored dependency of SHG versus deposited charge.

Example 14. The system of any of Claims 11-13, wherein said electronics are configured to estimate an interface state density based on a comparison between (a) a dependency of the measured SHG versus charge deposited and (b) a dependency of SHG versus deposited charge for a sample having less states.

Example 15. The system of any of Claims 11-14, wherein said electronics are configured to estimate an interface state density based on a comparison of (a) the shape of a first curve of SHG versus charge on the surface of the sample and (b) the shape of a second curve of SHG versus charge on the surface of the sample, wherein said first curved comprises measured SHG versus charge.

Example 16. The system of any of Claims 11-15, wherein said system is configured to form a guard region with charge having a first polarity and an inner region surrounded by said guard region having a second polarity having opposite said first polarity.

Example 17. The system of any of Claims 11-16, wherein said electrode is include in an electron gun.

Example 18. The system of any of Claim 17, further comprising an anode, at least one electron lens, and an electron beam deflector disposed with respect to the sample to direct electrons charge to the sample to place charge on the sample.

Example 19. The system of any of Claims 11-18, wherein said electrode is included in a scanning electron microscope (SEM) configured to deposit charge on said sample.

Example 20. The system of Claim 19, further comprising imaging the sample with the SEM.

Example 21. The system of Claims 1-4, 6-14 and 16-20, wherein said comparison comprises the difference in values of SHG for different amounts of applied charge.

### Group 4 (Guard Ring)

Example 1. A method of optical interrogation of a sample, the method comprising:
depositing electrical charge on or in the sample and/or charging the sample;
forming a guard region with charge having a first polarity and an inner region surrounded by said guard region having a second polarity having opposite said first polarity; applying probing radiation from a probing optical source to the sample, said probe radiation incident on said inner region;
detecting using an optical detector, Second Harmonic Generation (SHG) effect light generated by the probing radiation with said electrical charge deposited on or in the sample and/or charging of the sample.

Example 2. The method of Claim 1, wherein forming said guard region and said inner region comprises depositing charge of said first polarity over a larger area and depositing charge of said second polarity over a smaller area within said larger area such that said guard region surrounds said inner region.

Example 3. The method of Claim 1 or 2, wherein said sample comprise p-type semiconductor and said first polarity is negative and said second polarity is positive.

Example 4. The method of Claim 1 or 2, wherein said sample comprise n-type semiconductor and said first polarity is positive and said second polarity is negative.

Example 5. The method of any of the claims above, wherein said charge is deposited by an electron beam generation and scanning system comprising an electron gun, an anode, at least one electron lens, and an electron beam deflector disposed with respect to the sample to direct electrons to the sample to place charge on the sample.

Example 6. The method of any of the claims above, wherein said charge is deposited by a scanning electron microscope (SEM).

Example 7. The method of Claim 6, further comprising imaging the sample with the SEM.

Example 8. The method of any of the claims above, wherein said applying probe radiation comprise directing a laser beam from a probe laser to said inner region on said sample.

### Terminology

Example invention embodiments, together with details regarding a selection of features have been set forth above. As for other details, these may be appreciated in connection with the above-referenced patents and publications as well as is generally known or appreciated by those with skill in the art. The same may hold true with respect to method-based aspects of the invention in terms of additional acts as commonly or logically employed. Regarding such methods, including methods of manufacture and use, these may be carried out in any order of the events which is logically possible, as well as any recited order of events. Furthermore, where a range of values is provided, it is understood that every intervening value, between the upper and lower limit of that range and any other stated or intervening value in the stated range is encompassed within the invention. Also, it is contemplated that any optional feature of the inventive variations described may be set forth and claimed independently, or in combination with any one or more of the features described herein.

As used herein, a phrase referring to “at least one of” a list of items refers to any combination of those items, including single members. As an example, “at least one of: a, b, or c” is intended to cover: a, b, c, a-b, a-c, b-c, and a-b-c.

Though the invention embodiments have been described in reference to several examples, optionally incorporating various features, they are not to be limited to that which is described or indicated as contemplated with respect to each such variation. Changes may be made to any such invention embodiment described and equivalents (whether recited herein or not included for the sake of some brevity) may be substituted without departing from the true spirit and scope hereof. Certain features that are described in this specification in the context of separate implementations also can be implemented in combination in a single implementation. Conversely, various features that are described in the context of a single implementation also can be implemented in multiple implementations separately or in any suitable subcombination.

Moreover, although features may be described above as acting in certain combinations and even initially claimed as such, one or more features from a claimed combination can in some cases be excised from the combination, and the claimed combination may be directed to a subcombination or variation of a subcombination.

In one or more example embodiments, the functions described may be implemented in hardware, software, firmware, or any combination thereof. If implemented in software, the functions may be stored on, transmitted over or resulting analysis/calculation data output as one or more instructions, code or other information on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. The memory storage can also be rotating magnetic hard disk drives, optical disk drives, or flash memory based storage drives or other such solid state, magnetic, or optical storage devices.

Also, the inventors hereof intend that only those claims which use the words “means for” are to be interpreted under 35 USC 112, sixth paragraph. Moreover, no limitations from the specification are intended to be read into any claims, unless those limitations are expressly included in the claims. The computers described herein may be any kind of computer, either general purpose, or some specific purpose computer such as a workstation. The programs may be written in C, or Java, Brew or any other programming language. The programs may be resident on a storage medium, e.g., magnetic or optical, e.g. the computer hard drive, a removable disk or media such as a memory stick or SD media, or other removable medium. The programs may also be run over a network, for example, with a server or other machine sending signals to the local machine, which allows the local machine to carry out the operations described herein.

It is also noted that all features, elements, components, functions, acts and steps described with respect to any embodiment provided herein are intended to be freely combinable and substitutable with those from any other embodiment. If a certain feature, element, component, function, or step is described with respect to only one embodiment, then it should be understood that that feature, element, component, function, or step can be used with every other embodiment described herein unless explicitly stated otherwise. This paragraph therefore serves as antecedent basis and written support for the introduction of claims, at any time, that combine features, elements, components, functions, and acts or steps from different embodiments, or that substitute features, elements, components, functions, and acts or steps from one embodiment with those of another, even if the following description does not explicitly state, in a particular instance, that such combinations or substitutions are possible. It is explicitly acknowledged that express recitation of every possible combination and substitution is overly burdensome, especially given that the permissibility of each and every such combination and substitution will be readily recognized by those of ordinary skill in the art.

In some instances entities are described herein as being coupled to other entities. It should be understood that the terms “interfit”, “coupled” or “connected” (or any of these forms) may be used interchangeably herein and are generic to the direct coupling of two entities (without any non-negligible, e.g., parasitic, intervening entities) and the indirect coupling of two entities (with one or more non-negligible intervening entities). Where entities are shown as being directly coupled together, or described as coupled together without description of any intervening entity, it should be understood that those entities can be indirectly coupled together as well unless the context clearly dictates otherwise.

Reference to a singular item includes the possibility that there are a plurality of the same items present. More specifically, as used herein and in the appended claims, the singular forms “a,” “an,” “said,” and “the” include plural referents unless specifically stated otherwise. In other words, use of the articles allow for “at least one” of the subject item in the description above as well as the claims below.

It is further noted that the claims may be drafted to exclude any optional element (e.g., elements designated as such by description herein a “typical,” that “can” or “may” be used, etc.). Accordingly, this statement is intended to serve as antecedent basis for use of such exclusive terminology as “solely,” “only” and the like in connection with the recitation of claim elements, or other use of a “negative” claim limitation language. Without the use of such exclusive terminology, the term “comprising” in the claims shall allow for the inclusion of any additional element—irrespective of whether a given number of elements are enumerated in the claim, or the addition of a feature could be regarded as transforming the nature of an element set forth in the claims. Yet, it is contemplated that any such “comprising” term in the claims may be amended to exclusive-type “consisting” language. Also, except as specifically defined herein, all technical and scientific terms used herein are to be given as broad a commonly understood meaning to those skilled in the art as possible while maintaining claim validity.

While the embodiments are susceptible to various modifications and alternative forms, specific examples thereof have been shown in the drawings and are herein described in detail. It should be understood, however, that these embodiments are not to be limited to the particular form disclosed, but to the contrary, these embodiments are to cover all modifications, equivalents, and alternatives falling within the spirit of the disclosure. Furthermore, any features, functions, acts, steps, or elements of the embodiments may be recited in or added to the claims, as well as negative limitations (as referenced above, or otherwise) that define the inventive scope of the claims by features, functions, steps, or elements that are not within that scope. Thus, the breadth of the inventive variations or invention embodiments are not to be limited to the examples provided, but only by the scope of the following claim language.

1. A system for optically interrogating a sample accompanied by the application of electric charge to said sample, said system comprising:
an electron beam generation and scanning system comprising an electron gun, an anode, at least one electron lens, and an electron beam deflector disposed with respect to the sample to direct electrons to the sample to place charge on the sample;
a vacuum system comprising a vacuum chamber and a vacuum pump, said electron gun, said anode, said at least one electron lens, said electron beam deflector and said sample included in said vacuum chamber;
a probe optical source configured to emit probing light, said probe optical source disposed so as to direct said probing light onto said sample; and
an optical detector configured to detect second harmonic generated (SHG) light from the sample in response to said probing light directed thereon.

2. The system of claim 1, wherein said at least one electron lens comprises an objective.

3. The system of claim 1, further comprising an electron detector in said vacuum chamber.

4. The system of claim 1, wherein said probe optical source comprises a pulse laser and said optical detector comprise a photovoltaic, a photoconductor, or a photomultiplier tube.

5. The system of claim 1, wherein said vacuum chamber has a window or fiber feedthrough for transmission of said probing light into said vacuum chamber.

6. The system of claim 1, further comprising a chuck for supporting said sample.

7. The system of claim 6, further comprising an ammeter electrically connected to said chuck to measure charge flow from said chuck.

8. The system of claim 6, further comprising a high voltage source electrically connected to said chuck to apply a voltage to said sample.

9. The system of claim 1, wherein said electron beam generation and scanning system comprises a scanning electron microscope (SEM).

10. The system of claim 9, wherein said scanning electron microscope has a work distance of no less than 5 millimeters (mm).

11. The system of claim 1, further comprising electronics configured to receive an electronic signal from said optical detector.

12. The system of claim 11, wherein said electronics are configured to determine a characteristic of the sample based on a variation in the detected SHG light with different amount of electrical charge deposited on or in the sample and/or the charging of the sample.

13. The system of claim 11, wherein said electronics are configured to receive an electronic signal from said optical detector to determine a characteristic based on said SHG light.

14. The system of claim 11, wherein said electronics are configured to monitor the SHG signal for varying amounts of charge deposited on or in the sample by the electron beam generation and scanning system and/or for varying amounts of charging of the sample by the electron beam generation and scanning system.

15. The system of claim 11, wherein said electronics are configured to estimate a density of states based on said SHG signal.
